(19) United States
(12) Patent Application Publication
(10) Pub. No.: US 2008/0115967 A1
(43) Pub. Date: May 22, 2008

(54) Shield For A Microwave Circuit Module

(76) Inventors: Kirk S. Giboney, Santa Rosa, CA (US); Xiaohui Qin, Santa Rosa, CA (US); Paul E. Cassanego, Santa Rosa, CA (US); Robin L. Zinsmaster, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/608,084

(22) Filed: Dec. 7, 2006

Related U.S. Application Data
(60) Provisional application No. 60/866,945, filed on Nov. 22, 2006.

(51) Int. Cl. H05K 9/00

(52) U.S. Cl. 174/351

(57) ABSTRACT

A shield for an electronic circuit for controlling electromagnetic radiation. The circuit is constructed on a PCB having a minimum of three metal layers. The PCB includes SMT shield connectors for carrying signals to the circuit. The shield includes a metal wall portion mounted to the PCB and a removable metal lid mounted to the wall portion. The PCB, connectors, wall portion and lid together form a continuous electromagnetic barrier around the circuit.

### BACKGROUND OF THE INVENTION

This application claims priority under 35 USC § 120 from Application Ser. No. 60/866,945 filed Nov. 22, 2006, entitled “SHIELDED MICROWAVE CIRCUIT MODULE”, which is incorporated herein by reference.

This invention relates to electromagnetic shielding of electronic circuits. More particularly, this invention relates to shielding of microwave circuits (microcircuits) for controlling electromagnetic radiation.

Shielding improves microwave circuit performance by reducing interference of one part of the circuit with another part of the circuit. Shielding also reduces the interference from sources outside of the circuit, as well as reducing interference to other circuits caused by a particular circuit.

Shielding of a circuit is typically accomplished by enclosing it in metal. The thickness and conductivity of the metal determine the shielding effectiveness. Openings in the shielding provide access to the signals inside, yet also degrade shielding effectiveness, depending on their size, geometry, number, and placement.

It is also possible to shield using materials that absorb the electromagnetic energy, such as resistive or magnetic materials. However, this approach risks a possible compromise in circuit efficiency and performance, and it adds to the complexity and cost to the circuit.

When a source of electromagnetic energy is enclosed in a conductor, radiated energy can reflect from the conductor surfaces. If the frequency of the electromagnetic wave is near a natural frequency of a shielded circuit, then resonances are possible. Resonances can be detrimental to the performance of the microwave circuit.

An enclosure with dimensions less than one-half wavelength after accounting for all structures and materials present will not support such cavity resonances. Resonances may also be controlled by the use of electromagnetic absorbing materials with the same disadvantages as for using these materials for shields.

Traditionally, shielding is achieved in microwave circuits by enclosing them in metal. A prior art hybrid microcircuit 10 shown in FIG. 1 is based on a machined metal block 11 that is closed with a metal lid (not shown). The hybrid microcircuit 10 consists of components such as integrated circuits (ICs) 12 and thin-film circuits 13 having wirebonds, microwave connectors 14 (which are so-called spark plug RF connectors), and low-frequency and power connectors 15 within channels and cavities 16 in the machined metal block 11. The channels and cavities 16 serve to cut off unwanted resonances from being produced in the microcircuit 10. The metal block 11 is precision machined and gold plated with mounting holes 17.

The hybrid microcircuit approach to building microwave circuits typically provides the best microwave performance and it is a well-established art. However, it supports only a low degree of integration since interconnection is provided by individual thin-film substrates. Bias and support circuitry is usually only practical on a separate printed-circuit board (PCB). Manufacturing cost is relatively high because fabrication of the base metal housing is serial rather than batch and the assembly processes are difficult to automate. Hybrid microcircuits are typically bulky and heavy.

Conventional PCBs are comprised of layers of metal separated by layers of dielectric material and interconnected by vias. The metal layers in a PCB together with arrays of vias can enclose internal structures and serve as shielding. The shielding effectiveness of the arrays of vias approaches that of continuous metal as the via spacing decreases.

The lateral shielding of a PCB can be improved over that afforded by vias by plating the edges of the PCB so that the edges and the layers of the PCB together form a continuous metal enclosure. Thus, to the degree that PCB shielding is effective, shielding continuity can be maintained by mounting shielded packages to a shielded PCB.

Small circuits are often shielded within transistor-outline (TO) can packages or in surface-mount technology (SMT) packages for example, that comprise formed sheet metal or patterned metal films deposited on dielectrics for shielding. Such packages are mounted to PCBs.

The mounting of pre-packaged devices to PCBs affords flexibility and efficiency for high-volume applications. The use of PCB allows for higher complexity, higher density circuits than is possible with a hybrid microcircuit approach. This approach results in smaller and lighter circuits than a hybrid microcircuit would, and it is ultimately limited by the package sizes and geometries. Packages consume larger area than required for the bare die, and packages introduce extra electrical interfaces, which limit frequency range for the circuits.

FIG. 2 depicts a prior art PCB 20 having various packages 21 and 22. Metal lids 23 and 24 are attached to the PCB 20 for shielding the components of packages 21 and 22, respectively. The metal lids 23 and 24 form the top and sides of an enclosing box. The bottom of the box is provided by a metal pattern 25 on the PCB.

Another approach to shielded microcircuits is shown in prior art FIG. 3 which depicts a cross section of an inventive package 30 having two distinct PCBs as both top and bottom shields. The package 30 is an embodiment of an invention described in U.S. Pat. No. 6,137,693, issued Oct. 24, 2000 which is hereby incorporated by reference and which is assigned to Agilent Technologies, the same assignee as the present invention. A PCB in the form of a daughter substrate 31 is operably coupled by arbitrarily shaped solder interconnects 32 and conventional solder ball interconnects 38 to a PCB in the form of a mother substrate 34. The substrate 31 is also operably coupled to a variety of SMT components 35, wirebond connected devices 36 and so-called flip-chip devices 37. Arbitrarily shaped solder interconnects 32 and conventional solder ball interconnects 38 form electrical connections between metal interconnects on the mother and daughter substrates 34,31. It should be explained that metal interconnects 33 are parts of conventional patterns of solderable metallization formed on the PCBs. The PCBs are attached to each other and shielding is completed by a continuous solder connection or solder wall formed of interconnects 32. The solder wall comprises a mechanical structure, connecting the PCB substrates 31 and 34 at a specified separation, an environmental seal (which is not shown and which prevents moisture and contamination from entering the interior), an electromagnetic shield and an electrical ground connection. Integrated circuit die can also be mounted and wirebond connected to the PCB inside the shield. Solder structures also complete electrical interconnection between the stacked PCBs. Typically, a smaller microwave circuit is attached in this manner to a larger motherboard with lower frequency circuitry.

Using solder to connect and shield two PCBs builds upon existing ball-grid array technology to fabricate shielded microwave circuits. This approach supports mounting of bare die directly to the PCB, which reduces size and weight, and it eliminates an electrical interface that limits microwave performance. Forming custom shielding cavities around the bare die allows high-density circuits and high-frequency operation without resonances.

The characteristics of molten solder restrict the geometries that can be used for the solder walls. This makes design of the modules more complex and ultimately limits the practical frequency range that can be addressed when using solder wall with PCBs for shielded circuits. Furthermore, the board-to-board separation is also limited by the solder design and tall components require PCB routing to accommodate them. For example, PCB routing 39 in the mother substrate 34 accommodates the flip-chip devices 37. Special test fixturing is required to contact the solder ball interconnects for testing the PCB halves before final assembly. The fully assembled modules cannot be effectively reworked. Notably, there is a relatively large quantity of lead in solder walls and interconnects compared to other microwave circuit module shielding approaches.

Shielded coaxial connectors maintain shield continuity between circuits and microwave cables that carry signals to be transmitted to the circuits. SMT shielded coaxial connectors used with PCBs are typically soldered to the PCB. The solder bridges the shield of the surface metal layer of the PCB with the shield of the connector. The shield of the SMT shielded coaxial connector surrounds the center conductor and couples to the surface metal shield of the PCB to enclose the center conductor. The center conductor connects with a blind via that connects to a signal conductor formed in inner metal layers of the PCB, where they are shielded by metal of the top and bottom surface layers of the PCB and by vias on the sides. An example of an SMT connector for use in the present invention is the edge-launch connector 50 shown in FIGS. 4A-4C.

The edge-launch connector 50 is described in detail in U.S. Patent Application Publication No. U.S. 2004/0119557, published Jun. 24, 2004, which issued as U.S. Pat. No. 7,042,318 (the '718 patent). The '718 patent is hereby incorporated by reference and is assigned to Agilent Technologies, the same assignee as the present invention. The connector 50 is used with a variety of PCBs, including PCBs having different thicknesses.

FIG. 4A shows an isometric view of a shielded edge launch connector 50 for use in the present invention. The connector 50 includes a coaxial connector interface 51, a shielded transition block 52, a pin support 55, and a center pin 54. The portion of the center pin that extends from the pin support 55 into the shielding cavity 58 will be referred to as the center pin 54 for purposes of discussion, even though the center pin also extends into the pin support 55. The pin support 55 is a solid dielectric material, such as TEFLON™ or glass. The shielded transition block 52 includes shielding 56 that forms a shielding cavity 58 extending beyond the tip 59 of the center pin and covers the center pin 54 when the shielded edge launch connector 50 is soldered to a surface (e.g. top or bottom side) of a PCB.

High-frequency circuits are often manufactured on printed circuit assemblies (PCAs). The shielded edge launch connector 50 provides a transition from the coaxial connector interface 12 to a controlled impedance transmission structure of a PCB or other circuit for communicating high-frequency signals to and from the PCA. The controlled impedance structure of the PCB is often a planer transmission line, for example. The shielding 56 electromagnetically shields the transition from the coaxial transmission structure of the shielded edge launch connector to the controlled impedance transmission structure of the PCB.

Furthermore, the shielding cavity 58 can be shaped to operate in cooperation with the center pin 54 to provide a controlled impedance transmission structure in the shielded edge launch connector 50. The shielding 56 wraps the ground structure of the coaxial connector interface 51 to the surface (e.g. top side) of the PCB to improve the impedance match of the center pin 54 after it leaves the pin support 55 to the impedance of the coaxial connector interface 51. Providing a shielding cavity with controlled impedance reduces the impedance discontinuity between the coaxial and planar transmission structure. Similarly, providing a shielding cavity with controlled impedance reduces the sensitivity of the PCA to PCB thickness and edge tolerances. As used herein, the term ground refers to the potential of the outer conductor of the coaxial connector interface 51.

The shielded transition block 52 is electrically conductive, and is typically made of metal. In some embodiments of the connector 50, the coaxial connector interface 51 is integrated with the shielded transition block 52, and in other embodiments the shielded transition block is configured to accept a coaxial connector interface, such as an SMA barrel, that is screwed or otherwise coupled to the shielded transition block.

An optional view port 60 is provided to inspect the solder joint between the center pin 54 and the PCB. In one embodiment of connector 50, an automated solder paste deposit and oven reflow technique is used to solder the shielded edge launch connector to the top surface of a PCB. It is believed that the automated solder paste deposit and reflow process provides superior RF performance compared to hand-soldering techniques because the amount and placement of the solder paste is more controllable, particularly with machine-vision solder paste inspection. After solder reflow and inspection of the center pin solder joint, a metal lid 62 is press fit, and optionally soldered, into the view port 60, electrically sealing the shielding transition block 52.

The shielded transition block 52 has sidewalls 64 that engage a cutout in the PCB. In other words, the sidewalls 64 overhang the sides of the cutout and support the shielded edge connector during PCA fabrication. The sidewalls also provide soldering surface area for a strong mechanical interface between the shielded edge launch connector and the PCB. Automated SMT pick-and-place equipment provides accurate placement of the shielded edge launch connector on the PCB. The shielded edge launch connector 50 is typically pressed against the side of the PCB during solder reflow to keep an end wall 66 in contact with the edge of the PCB, and thus reduce the impedance discontinuity at the board edge. The end wall 66 is typically soldered to the bottom edge of the PCB for improved electromagnetic shielding and strength.

FIG. 4B shows a plan view of a PCA 70 with the shielded edge launch connector 50 of FIG. 1A mounted on a PCB 72. The shielded edge launch connector 50 is connected to a controlled impedance transmission line (not shown) formed in the PCB 72. The shielded edge launch connector 50 is used with a variety of PCBs, including PCBs having different thicknesses.

FIG. 4C shows a cross section of the system 70 of FIG. 4B taken along section line A-A. The PCB 72 has metal layers 74, 76, 78, 86 separated by dielectric layers 80, 82, 84. Other PCBs have more or fewer layers. Metal layers are typically patterned to define electric circuits. A variety of dielectric materials, such as GETEC™ available from COOKSON ELECTRONICS PWB MATERIALS AND CHEMISTRY of Londonderry, N.H., or RO4350™, available from ROGERS CORP. of Chandler, Ariz., are suitable for use in a PWB having controlled impedance transmission structures.

The center pin 54 and shielding 56 are reflow soldered to exposed portions of a first patterned metal layer 74. The view port 60 allows visual inspection of the solder joint of the center pin 54 to a center pin solder pad 88. The center pin solder pad 88 couples the electronic signal from the center pin 54 to a center conductor via 90, which couples the electronic signal to a center conductor 92 formed in patterned metal layer 76. The center conductor via 90 is generally a plated hole that is optionally filled with solder. Vias are used to make electrical connections between layers of metal in PCBs. Metal layers 74, 78 form ground planes that work in cooperation with the center conductor 92 to form a planar controlled impedance transmission structure in the PCB 72.

Vias that do not extend through all layers of the PCB 72 are referred to as “blind” vias. Alternatively, a center conductor via extends all the way through the PCB to couple the electric signal from the center pin 54 to a controlled impedance transmission structure on the opposite side 91 (“bottom”) of the PCB. A via extending through the PCB is also known as a through via. The back wall 66 of the shielded edge launch connector 50 is soldered to the metal layer 86, as are the sides of the shielded transition block 52 (not shown) to form a contiguous perimeter of solder between the PCB 72 and the shielded edge launch connector 50, providing complete electromagnetic shielding.

FIG. 4D depicts a cross sectional view of another SMT style shielded connector 100 used in the present invention and attached to a PCB 150. The attachment is made using solder or similar eutectic bonding material. The PCB 150 comprises multilayers having a first surface, a second surface that is opposite the first surface, and a buried stripline transmission line 156. The first surface has a first or top ground plane 152, the second surface has a second or bottom ground plane 154 and the buried stripline transmission line 156 is located between the ground planes 152, 154. The PCB 150 further has a blind via 158 that extends from the buried stripline to the first surface. The blind via 158 connects a solder pad 160 on the first surface to the stripline 156. The blind via 158 and the solder pad 160 are electrically isolated from the ground planes 152,154. The coaxial connector 100 is attached to the top ground plane 152 by soldering, or otherwise electrically and mechanically affixing an annular flange 119 of the connector 100 to the top ground plane 152. A center pin 120 may be soldered or otherwise electrically and mechanically affixed to the solder pad 160 to complete the attachment of the shielded SMT coaxial connector 100. The connector 100 is described in detail in U.S. Pat. No. 6,992,544, issued Jan. 31, 2006 which is hereby incorporated by reference and which is assigned to Agilent Technologies, the same assignee as the present invention.

### SUMMARY OF THE INVENTION

The present invention provides a shielded microwave circuit module in which a printed-circuit board (PCB) serves as the base and supports the interconnection of electronic components. Components are attached and electrically connected to the PCB either by standard surface-mount technology (SMT) or by known die attach and wirebond techniques.

Components normally used on PCBs can be suitably attached and included in the module. Solid metal custom prescribed wall structures, designed in accordance with the descriptions given in the prior section, are conductively attached to the PCB. Integrated-circuit bare-die are mounted and wirebonded to the PCB within the metal shields. Custom prescribed lids, designed with the prescribed wall structures, are conductively attached to the tops of the wall structures to complete the electromagnetic shields and protect the enclosed components. High-frequency interconnection can be provided by wirebonds and PCB metal patterns and vias. Shielded coaxial connectors surface-mounted to the PCB provide for shielded connection to other circuits.

The use of solid metal structures for the walls allows for arbitrarily small features and so poses no fundamental limitation to the circuit performance or geometries. The circuits can be fully tested before they are sealed and rework is feasible and practical at all stages of manufacturing assembly. This invention can employ standard electronics assembly processes for manufacturing relatively light and compact microcircuit modules having a high degree of complexity.

### BRIEF DESCRIPTION OF THE DRAWINGS

FIG. 1 depicts a prior art hybrid microcircuit.

FIG. 2 shows a prior art PCB having components and shields.

FIG. 3 depicts a prior art shield.

FIGS. 4A-4D show two prior art SMT shield connectors.

FIG. 5 depicts a bare PCB used in an embodiment of the present invention.

FIG. 6 shows a microcircuit module.

FIG. 7 depicts a portion of a custom designed walls used in an embodiment of the present invention.

FIG. 8 shows a section of joints used in an embodiment of the present invention.

FIG. 9 depicts a portion of the custom designed walls used in an embodiment of the present invention.

FIG. 10 shows edge-to-edge bonds used in an embodiment of the present invention.

FIG. 11 depicts a microcircuit module.

FIG. 12 shows a bottom portion of a microcircuit module.

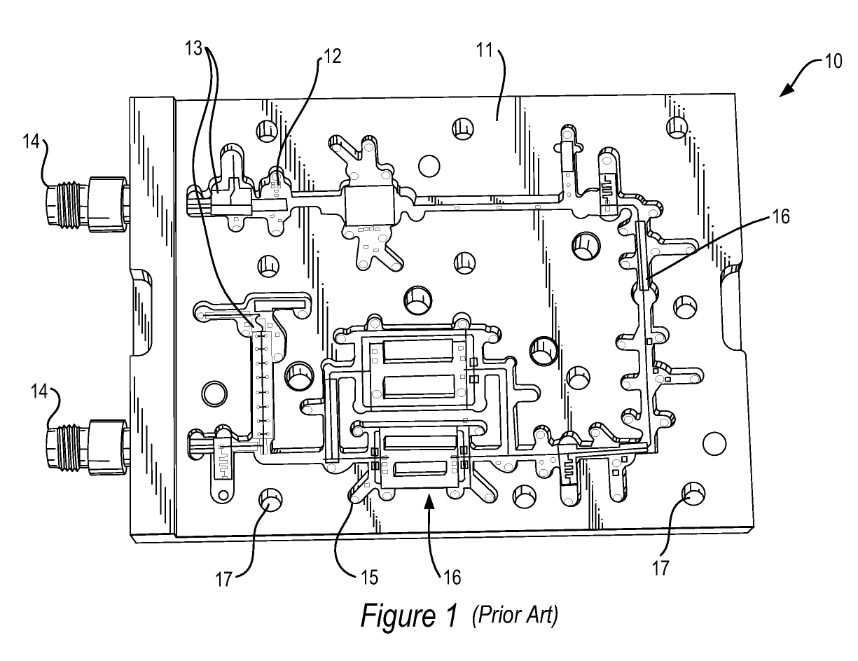

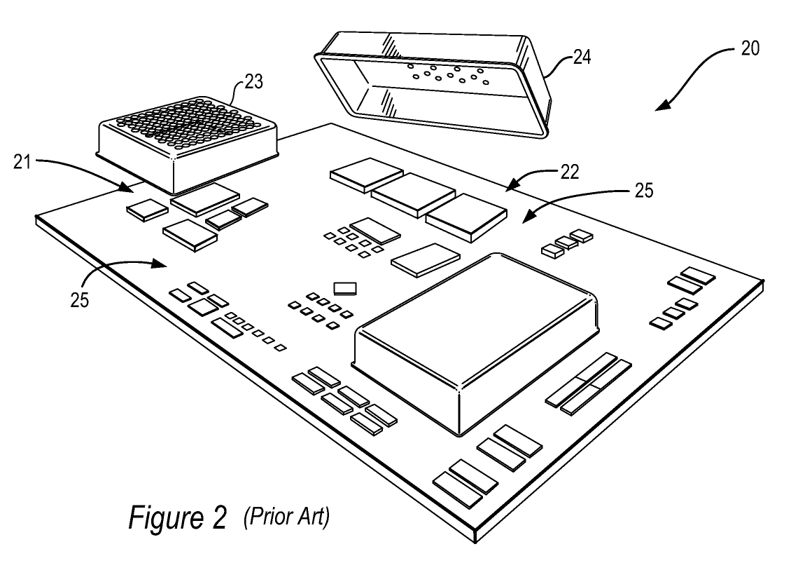

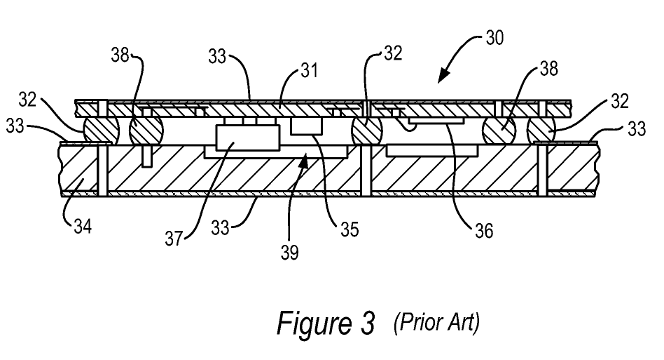

It should be understood that like reference numbers in the figures refer to similar items.

### DETAILED DESCRIPTION

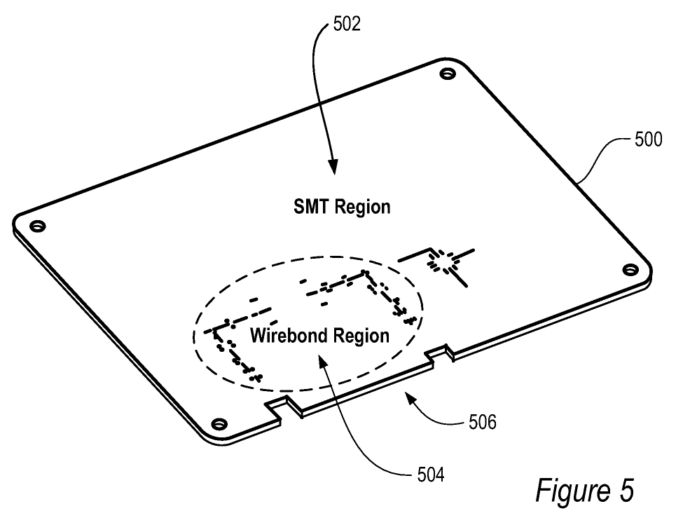

With reference to FIG. 5, the construction of a microcircuit module incorporating the present invention begins with a bare PCB 500. Normally, the PCB 500 would preferably have at least four metal layers and be constructed of well-known materials and processes. However, the present invention will operate with a minimum of three metal layers. The PCB of an exemplary embodiment of present invention to be described in this section has six metal layers laminated with epoxy-glass-silica-fill laminate dielectric layers. It should be understood that the exemplary embodiment is for understanding the teachings of the present invention which is not limited to this exemplary embodiment. The PCB 500 includes an SMT region 502 for mounting conventional SMT components, packages and devices as well as a wire bond region 504 for mounting wirebond components, packages and devices. Conventional blind vias (not shown in FIG. 5) are used for transitions and shielding and wirebond regions are selectively plated with bondable gold 506.

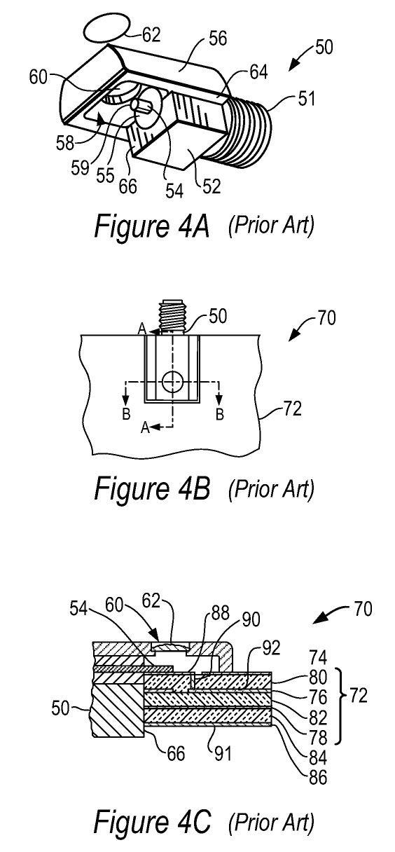

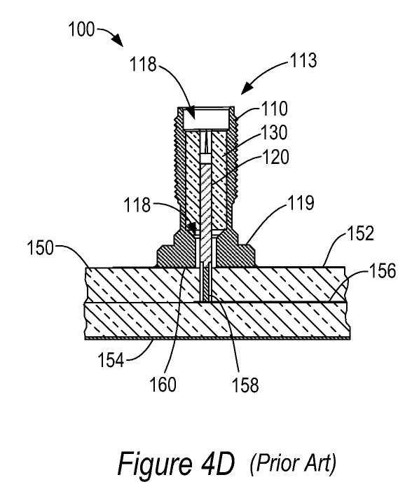

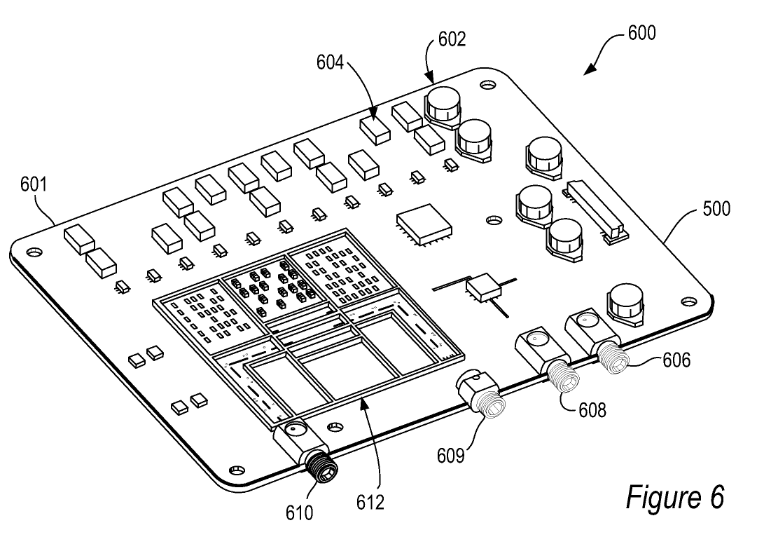

In making the exemplary embodiment, a first assembly process is 2-sided surface mount attachment. FIG. 6 shows a microcircuit module 600 after the SMT process is used for mounting SMT packaged components 602, 604. The SMT components may be attached to both sides of the PCB 500 (top & bottom). The SMT components may include connectors, resistors, capacitors, inductors, transistors, diodes, packaged ICs, standard shields, or any component that can be attached to the PCB 500 using an SMT process. SMT shielded microwave connectors 606, 608 and 610 are mounted to the PCB 601 and custom designed walls 612 (to be described later in more detail) are attached to the top. The SMT shielded microwave connectors 606, 608, 609, 610 may be the edge-launch style or other shielded SMT connectors (such as the connector 100 depicted in FIG. 4D).

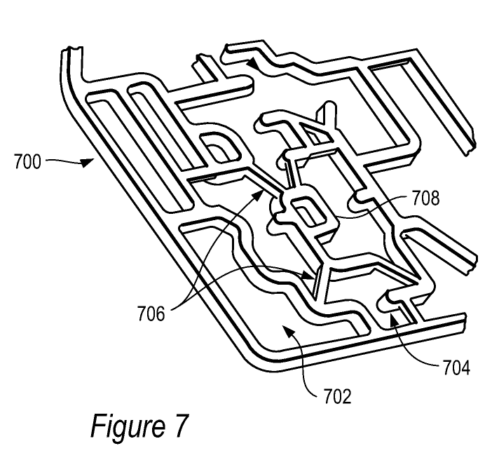

A custom shield made in accordance with the teachings of one embodiment of the present invention includes a plurality of custom walls and corresponding lids. The custom walls and lids are preferably fabricated in processes that afford the feature sizes and tolerances needed to control electromagnetic modes and accommodate the electronic circuits, components and devices that will be enclosed within the shield. Each portion of the custom walls are fabricated in low volumes by conventional milling of sheet stock and in medium volumes by chemical milling. In high volumes, stamping or casting is used to fabricate the wall parts. The lid is fabricated from sheet stock in low to medium volumes by chemical milling and in high volumes, preferably by stamping. FIG. 7 shows a portion of a specific design of a custom wall 700 where areas 702, 704 respectively will enclose the electronic circuits, components and devices that require shielding to control electromagnetic radiation. It should be understood that the prescribed volumes formed by each of the areas 702 and 704 when mounted to the PCB 500 (not shown in FIG. 7) and covered by the lid (also not shown) are custom designed so that the prescribed electronic circuits, components and devices enclosed by the respective volumes will be shielded to control electromagnetic radiation.

The wall 700 includes so-called bridges 706. The bridges 706 enable a so-called island 708, which is a wall structure that is free-standing at the base. When the wall 700 is mounted to the PCB, the bridges 706 are designed so as not to contact the PCB but will be bonded to the lid when it is mounted to cover the wall 700. Although not shown in FIG. 7, other bridges that are designed to be bonded to the PCB when the wall 700 is mounted thereon but not the lid is a so-called upside-down bridge and serve as vents. The wall 700 may be formed as a unitary structure for mounting onto the PCB 500. Alternatively, the wall 700 may be an assemblage of pieces. Various portions of the wall may be mounted to the PCB 500 at times different from one another as may be needed for manufacturing a particular microcircuit module.

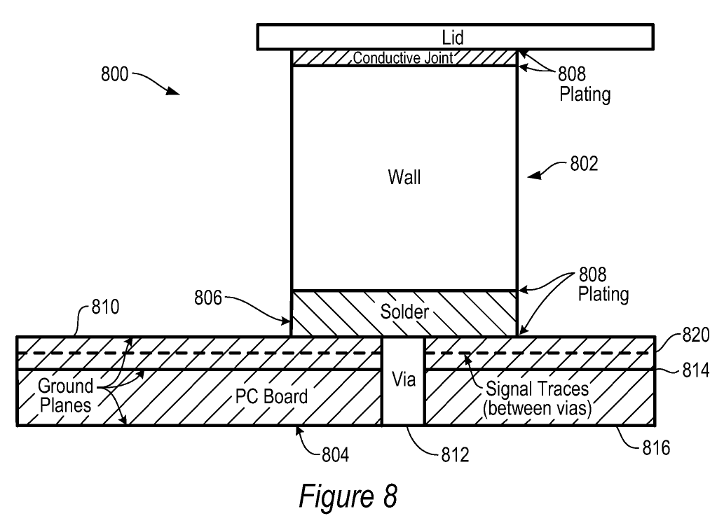

FIG. 8 shows a conceptual cross-section of a joint 800 used in one embodiment of the present invention. A wall 802 is mounted to a PCB 804 via a solder 806 bond. There are plating layers 808, which are preferably gold, for ensuring a good bond between the solder 806 and the wall 802 and a metal ground plane 810 formed on the PCB 804. This joint 800 must have sufficient solder to: (1) avoid gold embrittlement from gold dissolved into solder from wall and into the metal ground plane 810 and (2) provide sufficient standoff to absorb mechanical stresses between the wall 802 and the PCB 804. A through via 812 connects the ground planes 810, 814 and 816 to form the lower part of the metal shield of the microcircuit module. A stripline 814 is shown which carries signals from the connectors (not shown in FIG. 8) to various portions of the module. The stripline 814 does not contact the through via 812 and is shielded by the ground planes 810 and 814.

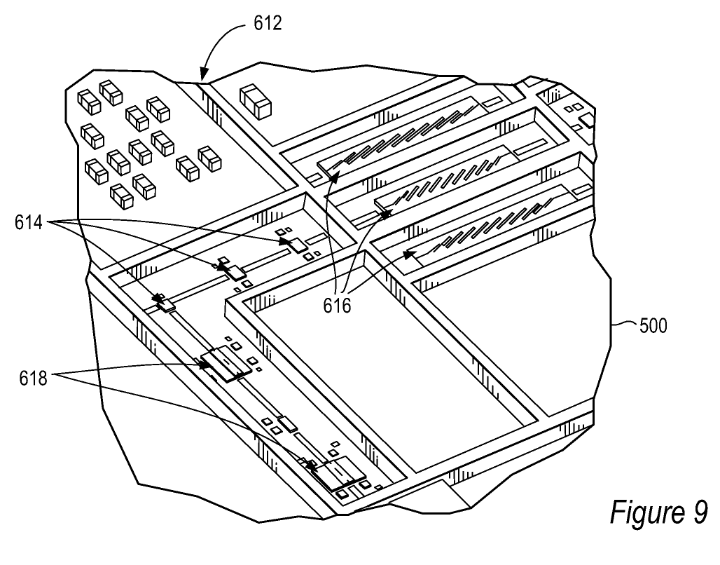

FIG. 9 is a more detailed portion of the custom designed walls 612 and the microcircuit module 600 shown in FIG. 6. ICs 614, thin film circuits 616, and other wirebonded components are attached to the PCB 500. This is typically done in two phases (layers) to accommodate ICs 618 mounted on shims or thin film circuits. The wirebond connections are made with wedge bonds.

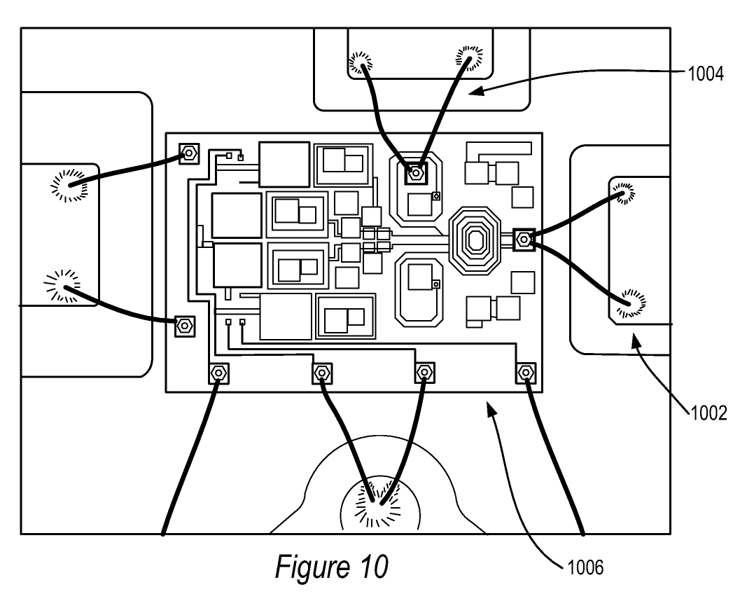

FIG. 10 shows edge-to-edge bonds 1002, 1004 on an IC 1006 for wires that are used for microwave paths in the microcircuit module 600. These bonds are described in detail in U.S. Patent Publication No. 2005/0083153, published Apr. 21, 2005 which is hereby incorporated by reference and which is assigned to Agilent Technologies, the same assignee as the present invention.

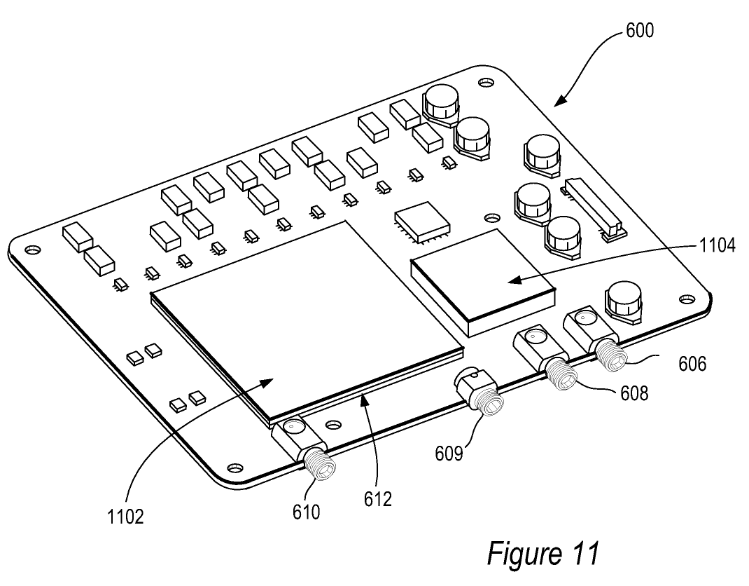

FIG. 11 shows the microcircuit module 600 after all of the connections have been made and electrical tests conducted to confirm basic functionality. Rework is performed as necessary if any of the electrical tests have failed. A sheet metal lid 1102 for the custom designed walls 612 (now covered by the lid 1102) is then attached with an electrically conductive adhesive. It should be understood that the lid 1102 can be fabricated as a single sheet or as various sections as needed for the prescribed volumes to be created when the lid 1102 is mounted on the walls 612. A lid 1104 covers another part of the microcircuit module 600 with a custom designed wall 1106. The lids 1102, 1104 preferably have holes (not shown) in them to allow pressure equalization and venting of gases during the adhesive curing process. The upside-down bridges previously mentioned serve as vents. The holes are closed by adhering sheet metal dots over them or by soldering over them.

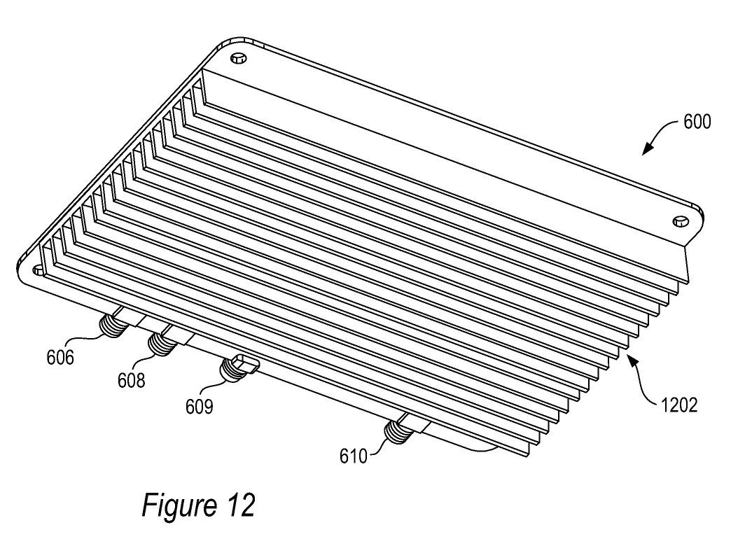

FIG. 12 shows the bottom side of the microcircuit module 600 with a heatsink 1202 mounted. Other devices such as brackets and any other external components that may be needed are attached to the microcircuit module 600 in the last assembly step. The module is preferably tested, again, as a final check. Any of the circuits, components and devices within the shields of the present invention may be reworked again by removing the lids 1102, 1104 as needed. The lids 1102,1104 are typically removed by first heating, which softens the adhesive, and then by subsequent prying and peeling. The residual adhesive is cleaned off and the necessary repair conducted. A new lid is attached with the electrically conductive adhesive and sealed, as previously described. Alternatively, the prior used lid may be re-attached if it is suitable.

With reference to FIGS. 5-12, a description will now be given describing the operation of the microcircuit module 600 as further explanation of the present invention. Electrical power and low-frequency control voltages and signals are supplied to the circuits in the microcircuit module 600 preferably through the SMT connectors 606,608, 609,610. High-frequency input and output signals are coupled through those constant-impedance shielded coaxial microwave connectors. Power and low-frequency circuitry is predominantly located outside of the custom shields regions, while the high-frequency signals are preferably contained within the custom designed shields of the present invention.

The custom designed shields control electromagnetic energy within the prescribed volumes of the shielded regions surrounding the circuits of the microcircuit module 600. The dimensions of the custom walls 612,1106 are chosen such that when closed by the lid, the natural resonances of the shielded region occur at frequencies higher than the operating range of the circuits. The spacing between the walls and the height of the walls are specified to be less than one-half wavelength at the highest operating frequency after accounting for all materials present. When this is not possible, or when undesirable out-of-band resonances occur, electromagnetic absorbing materials are employed.

High-frequency signals are routed on the PCB preferably using stripline transmission lines outside the shield regions, and microstrip and stripline transmission lines passing under the bridges (e.g., the bridges 706) formed within the shield regions. Low-frequency and DC signals are routed throughout the PCB preferably with traces on inner layers. Blind and through vias are used for transitions between transmission line modes, connecting traces between layers, for circuit grounds, and for shielding to control electromagnetic radiation.

The walls 612,1106 are SMT-attached to the PCB ground plane 810 of the PCB top metal layer. A soldering region for the attach is defined by a solder mask. Directly under the walls, arrays of through vias form a shield within the PCB 500. Electrical signals traverse a wall through a break in the array of vias using a trace on an inner layer of the PCB 500. For high-frequency signals, a stripline transmission line is used. Within a shield region, microstrip transmission lines are preferred because they have relatively lower loss. Microstrip is kept continuous between different cavities of the shield by routing it under the bridges 706. The bridges 706 and islands 708 allow the option of keeping low-loss microstrip lines continuous across boundaries within the multi-cavity shield while maintaining the structural integrity of the custom walls 612,1106.

Connections with bare die ICs and thin-film circuits are preferably through wirebonds, in addition to connections to component backsides through die attach. Connections to packaged components that are attached by SMT are made through solder joints.

The circuit components perform actions on the signals such as controlling voltages or currents, switching, attenuating, amplifying, mixing, sampling, filtering, or other functions that might be required in high-frequency analog or digital circuits. Circuit components include all parts of the circuit, those attached to the PCB and the PCB, itself. For example, patterns of PCB metal layers may form filtering elements in an embodiment.

Circuit components produce heat that must be dissipated to keep them within their operating temperature range. Temperature is managed in the module by providing thermally conducting features that direct heat to surfaces of the module where it may be dissipated to the environment (ambient). Heat-generating components may be mounted on thermally conducting elements (layers), either separate elements or elements integral to the PCB, that efficiently spread the thermal energy. By spreading the thermal energy, the thermal resistance in passing through subsequent materials is reduced.

Through vias and metal planes provide the primary thermal conducting structures in the PCB. There are two primary heat paths from components within the shields to ambient: (1) down through the device to heat spreading layer(s), laterally in the heat-spreading layer(s), laterally through the PCB, up through the walls, and out the lid; and (2) down through the device to heat spreading layer(s), laterally in the heat-spreading layer(s), down through the PCB, and out the bottom of the PCB.

The custom shields provide environmental and mechanical protection normally required for bare die. The most common substance that degrades the reliability of bare die ICs is moisture. The construction of the custom shields greatly reduces the ingress of moisture. Moisture essentially does not pass through metals, but it will pass through most PCB dielectric materials and epoxies used for lid attach. Moisture ingress is minimized by cladding surfaces of the PCB with metal wherever possible and by attaching the lid with a thin, wide joint.

This invention was conceived as a platform for building microcircuit modules. As such, it is fundamentally a collection of components and techniques. The elements that distinguish this invention are the use of the two-part multi-cavity shields in combination with the shielded coaxial edge- or vertical-launch SMT connectors on a multilayer PCB. This new combination allows for a continuous and complete shield for the entire electronic circuit, component and device enclosed by the prescribed volume and including the portion protecting the connectors coupled to the circuit.

Although the present invention has been described in detail with reference to particular embodiments, persons possessing ordinary skill in the art to which this invention pertains will appreciate that various modifications and enhancements may be made without departing from the spirit and scope of the claims that follow.

We claim:

1. A shield for an electronic circuit, the shield comprising:
a printed circuit board (PCB) for mounting the circuit; the PCB comprising at least three metal layers;
an SMT shielded connector mounted to the PCB and coupled to carry signals to the electronic circuit;
a metal wall portion coupled to at least two of the metal layers in the PCB and mounted to the PCB via an electrically conductive first bonding material; the wall portion comprising a prescribed volume;
a removable metal lid coupled to the wall portion through an electrically conductive second bonding material;
wherein the PCB, connector, wall portion and lid together form a continuous electromagnetic barrier around the electronic circuit.

2. The shield of claim 1 wherein the PCB includes metal that forms a portion of the barrier on an outer surface of the PCB.

3. The shield of claim 1 further including vias that connect the metal layers of the PCB and form a portion of the barrier.

4. The shield of claim 1 wherein the circuit is wirebonded to the PCB within the prescribed volume.

5. The shield of claim 1 wherein the wall portion includes an island.

6. The shield of claim 5 wherein the wall portion includes bridges coupled to the island.

7. The shield claim 1 wherein the wall portion includes bridges.

8. The shield of claim 7 wherein the bridges form vents.

9. The shield of claim 1 wherein a hole is formed through the lid.

10. The shield of claim 9 wherein the hole is sealed with an electrically conductive patch.

11. The shield of claim 1 wherein the first bonding material is chosen from a material group comprising solder and braze.

12. The shield of claim 11 wherein the second bonding material is an adhesive that permits the lid to be relatively easy to remove.

13. The shield of claim 1 wherein the second bonding material is an adhesive that permits the lid to be relatively easy to remove.

14. The shield of claim 1 wherein first bonding material is thermally conductive.

15. The shield of claim 14 wherein the second bonding material is thermally conductive.

16. The shield of claim 1 wherein the second bonding material is thermally conductive.

17. The shield of claim 16 wherein a heat sink is thermally coupled to the lid.

18. The shield of claim 1 wherein the second bonding material is thermally conductive and wherein a heat sink is thermally coupled to the lid.

19. The shield of claim 1 wherein a heat sink is thermally coupled to the circuit on a side of the PCB opposite the side where the circuit is mounted.

20. A shield for microcircuits comprising:
a printed circuit board (PCB) for mounting the microcircuits, the PCB comprising at least three metal layers;
SMT shield connectors mounted to the PCB and coupled to carry signals to the microcircuits;
vias formed in the PCB for coupling to at least two of the layers;
a metal wall portion coupled to the vias; the wall portion comprising a plurality of prescribed volumes each containing a corresponding portion of the microcircuits; the wall portion being mounted to the PCB via an electrically conductive first bonding material chosen from a group comprising solder and braze;
a removable metal lid coupled to the wall portion via an electrically conductive and adhesive second bonding material; and
wherein the PCB, vias, connectors, wall portion, and the lid comprise a continuous electromagnetic barrier.

21. The shield of claim 20 wherein the wall portion is an integral structure.

22. A shield for a plurality of electronic circuits comprising:
a printed circuit board (PCB) for mounting the circuits; the PCB comprising at least three metal layers;
a metal wall portion comprising a plurality of prescribed volumes, each volume containing one or more of the electronic circuits; the wall portion formed as an integral structure and mounted to the PCB via an electrically conductive first bonding material;
a lid coupled to the wall portion via an electrically conductive and adhesive second bonding material
a plurality of SMT shield connectors mounted to the PCB and coupled to carry signals to one or more of the circuits; and
wherein the PCB, connectors, wall portion and the lid comprise a continuous electromagnetic barrier around each of the circuits.

23. The shield of claim 22 wherein the second bonding material is thermally conductive and wherein a heat sink is thermally coupled to the lid.

24. The shield of claim 1 wherein a stripline formed within the layers of the PCB is coupled to the connector and at least two of the metal layers shield the stripline to control electromagnetic radiation.

25. The shield of claim 20 wherein striplines formed within the layers of the PCB are coupled to associated connectors and at least two of the metal layers shield each stripline to control electromagnetic radiation.

26. The shield of claim 22 wherein striplines formed within the layers of the PCB are coupled to associated connectors and at least two of the metal layers shield each stripline to control electromagnetic radiation.
